(19) United States
(12) Patent Application Publication
(10) Pub. No.: US 2026/0331441 A1
(43) Pub. Date: Oct. 22, 2026

(54) PLASMA PROCESSING DEVICE

(71) Applicant: Tokyo Electron Limited, Tokyo (JP)

(72) Inventors: Shota EZAKI, Miyagi (JP); Masanori TAKAHASHI, Miyagi (JP); Kazuhito YAMADA, Miyagi (JP)

(73) Assignee: Tokyo Electron Limited, Tokyo (JP)

(21) Appl. No.: 19/696,336

(22) Filed: Jun. 3, 2026

Related U.S. Application Data
(63) Continuation of application No. PCT/JP2024/042448, filed on Dec. 2, 2024.

(30) Foreign Application Priority Data
Dec. 14, 2023 (JP) 2023-211156

(51) Int. Cl. H01J 37/32; H10P 72/00; H10P 72/72

(52) U.S. Cl. CPC H01J 37/32724; H10P 72/722; H01J 2237/2007; H01J 2237/334; H10P 72/0421

(57) ABSTRACT

A plasma processing device includes a plasma processing chamber, a substrate support pedestal, and a controller. The substrate support pedestal is in the plasma processing chamber, and includes a base and an electrostatic chuck on the base. The electrostatic chuck includes a first zone and a second, different zone. A first heater is in the first zone. A second heater is in the second zone. The controller controls a duty ratio of a pulse power applied to the first heater and a pulse power applied to the second heater, according to a resistance value ratio of a resistance value of the second heater with respect to a resistance value of the first heater, and a thermal resistance ratio of thermal resistance of the substrate support pedestal corresponding to the second zone with respect to thermal resistance of the substrate support pedestal corresponding to the first zone.

### CROSS-REFERENCE TO RELATED APPLICATIONS

This application is a continuation of International Application No. PCT/JP2024/042448, filed on Dec. 2, 2024 which claims the benefit of priority of the prior Japanese Patent Application No. 2023-211156, filed on Dec. 14, 2023, the entire contents of each are incorporated herein by reference.

### FIELD

Exemplary embodiments disclosed herein relate to a plasma processing device.

### BACKGROUND

Substrate processing systems can include a placement table on which a substrate is placed; a heater for heating the substrate when electrical power is supplied; a power supply part for supplying power to the heater; a sensor for measuring the resistance value of the heater; and a control arrangement. The control arrangement records a conversion table for mapping multiple resistance values to multiple temperatures, and acquires a reference resistance value measured by the sensor when the temperature of the heater is the reference temperature. Furthermore, the control arrangement acquires the resistance value for temperature control measured by the sensor when the substrate is heated by the heater, and controls the power supply part on the basis of the conversion table, the reference temperature, the reference resistance value, and the temperature control resistance value.

The present disclosure provides a technique for expanding the controllable temperature range in controlling the temperature of each zone to the same temperature.

### SUMMARY

In an embodiment of a present disclosure, a plasma processing device, includes: a plasma processing chamber; a substrate support pedestal disposed in the plasma processing chamber, and including a base and an electrostatic chuck disposed on the base; and a controller; wherein the electrostatic chuck includes a first zone and a second zone that is different from the first zone, a first heater is disposed in the first zone, a second heater is disposed in the second zone, and the controller is configured to control a duty ratio of a pulse power applied to the first heater and a pulse power applied to the second heater, according to a resistance value ratio of a resistance value of the second heater with respect to a resistance value of the first heater, and a thermal resistance ratio of thermal resistance of the substrate support pedestal corresponding to the second zone with respect to thermal resistance of the substrate support pedestal corresponding to the first zone.

### BRIEF DESCRIPTION OF DRAWINGS

FIG. 1 is a diagram for explaining a configuration example of a capacitively coupled plasma processing device according to an embodiment;

FIG. 2 is a plan view illustrating an example of the configuration of an electrostatic chuck according to one embodiment;

FIG. 3 is a sectional view illustrating an example of the configuration of the electrostatic chuck according to one embodiment;

FIG. 4 is a diagram for explaining the thermal resistance and calorific value of two zones in a substrate support unit;

FIG. 5A is a diagram for explaining an example of temperature control in a comparative example;

FIG. 5B is a diagram for explaining an example of temperature control in the comparative example;

FIG. 6A is a diagram for explaining an example when the temperature of a substrate is increased by the temperature control in the comparative example;

FIG. 6B is a diagram for explaining an example when the temperature of the substrate is lowered by the temperature control in the comparative example;

FIG. 7 is a diagram for explaining an example of temperature control in the present embodiment;

FIG. 8 is a diagram for explaining an example of a manufacturing flow of a substrate support unit according to the embodiment;

FIG. 9A is a diagram illustrating an example of the configuration of a heater according to the embodiment;

FIG. 9B is a diagram illustrating an example of the configuration of the heater according to the embodiment;

FIG. 9C is a diagram illustrating an example of the configuration of the heater according to the embodiment;

FIG. 9D is a diagram illustrating an example of the configuration of the heater according to the embodiment;

FIG. 9E is a diagram illustrating an example of the configuration of the heater according to the embodiment;

FIG. 9F is a diagram illustrating an example of the configuration of the heater according to the embodiment;

FIG. 9G is a diagram illustrating an example of the configuration of the heater according to the embodiment;

FIG. 10A is a diagram illustrating an example of the substrate support unit according to the embodiment;

FIG. 10B is a diagram illustrating an example of the substrate support unit according to the embodiment;

FIG. 10C is a diagram illustrating an example of the substrate support unit according to the embodiment; and

FIG. 10D is a diagram illustrating an example of the substrate support unit according to the embodiment.

### DESCRIPTION OF EMBODIMENTS

Hereinafter, exemplary embodiments of a plasma processing device disclosed in the present application will be described in detail with reference to the accompanying drawings. However, the disclosed plasma processing device is not limited to the present embodiment.

In a plasma process such as a plasma etching process and a film forming process, the processing state varies depending on the temperature of the substrate. Therefore, in the plasma processing device, the placing surface on which the substrate is placed is divided into a plurality of zones, and a substrate support pedestal capable of regulating the temperature of each zone is used. In such a substrate support pedestal, a heater is provided in each zone. In the plasma processing device, the temperature of each zone is controlled by supplying power to the heater in each zone of the substrate support pedestal, and causing the heater to generate heat.

Due to structural effects and the like, the thermal resistance of the substrate support pedestal varies from one zone to another. As a result, the controllable temperature range is narrowed in controlling the temperature of each zone in the substrate support pedestal to the same temperature.

Therefore, a technique for expanding the controllable temperature range in controlling the temperature of each zone to the same temperature is expected.

### Embodiment

### Device Configuration

An example of a plasma processing device of the present disclosure will be described. In the following embodiment, the plasma processing device of the present disclosure is used as a plasma processing system of the system configuration.

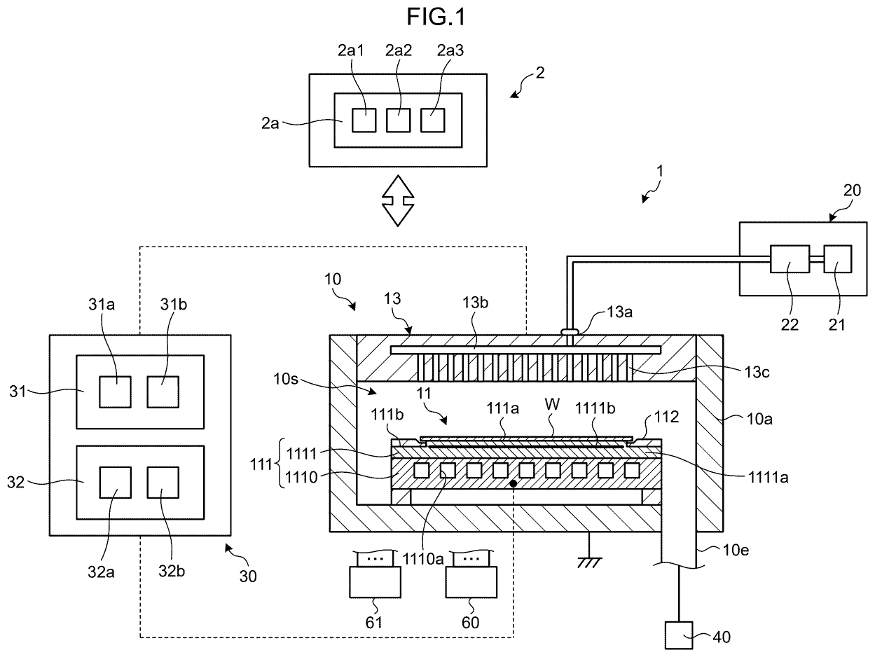

Hereinafter, a configuration example of a plasma processing system will be described. FIG. 1 is a diagram for explaining a configuration example of a capacitively coupled plasma processing device.

The plasma processing system includes a capacitively coupled plasma processing device 1 and a controller 2. The capacitively coupled plasma processing device 1 includes a plasma processing chamber 10, a gas supply unit 20, a power source 30, and an exhaust system 40. Moreover, the plasma processing device 1 includes a substrate support unit 11 and a gas introduction unit. The gas introduction unit is configured to introduce at least one processing gas into the plasma processing chamber 10. The gas introduction unit includes a shower head 13. The substrate support unit 11 is disposed in the plasma processing chamber 10. The shower head 13 is disposed above the substrate support unit 11. In one embodiment, the shower head 13 forms at least a part of the ceiling of the plasma processing chamber 10. The plasma processing chamber 10 includes a plasma processing space 10s defined by the shower head 13, a side wall 10a of the plasma processing chamber 10, and the substrate support unit 11. The plasma processing chamber 10 includes at least one gas supply port for supplying at least one processing gas to the plasma processing space 10s, and at least one gas discharge port for discharging gas from the plasma processing space. The plasma processing chamber 10 is grounded. The shower head 13 and the substrate support unit 11 are electrically insulated from the case of the plasma processing chamber 10.

The substrate support unit 11 includes a main body part 111 and a ring assembly 112. The main body part 111 includes a center region 111a for supporting a substrate W and an annular region 111b for supporting the ring assembly 112. A wafer is an example of the substrate W. The annular region 111b of the main body part 111 surrounds the center region 111a of the main body part 111 in a plan view. The substrate W is disposed on the center region 111a of the main body part 111, and the ring assembly 112 is disposed on the annular region 111b of the main body part 111 so as to surround the substrate W on the center region 111a of the main body part 111. Therefore, the center region 111a is also referred to as a substrate support surface for supporting the substrate W, and the annular region 111b is also referred to as a ring support surface for supporting the ring assembly 112.

In one embodiment, the main body part 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a includes the center region 111a. In one embodiment, the ceramic member 1111a also includes the annular region 111b. Other members that surround the electrostatic chuck 1111 such as an annular electrostatic chuck and an annular insulating member may also have the annular region 111b. In this case, the ring assembly 112 may be disposed on the annular electrostatic chuck or the annular insulating member, or may be disposed on both of the electrostatic chuck 1111 and the annular insulating member. Moreover, at least one RF/DC electrode that is coupled to a radio frequency (RF) power source 31 and/or a direct current (DC) power source 32, which will be described below, may be disposed in the ceramic member 1111a. In this case, at least one RF/DC electrode functions as a lower electrode. When a bias RF signal and/or a DC signal, which will be described below, is supplied to at least one RF/DC electrode, the RF/DC electrode is also referred to as a bias electrode. The conductive member of the base 1110 and at least one RF/DC electrode may function as a plurality of lower electrodes. Moreover, the electrostatic electrode 1111b may function as a lower electrode. Therefore, the substrate support unit 11 includes at least one lower electrode.

The ring assembly 112 includes one or more annular members. In one embodiment, the one or more annular members include one or more edge rings, and at least one cover ring. The edge ring is formed of a conductive material or an insulating material, and the cover ring is formed of an insulating material.

Moreover, the substrate support unit 11 may include a temperature adjusting module configured to regulate at least one of the electrostatic chuck 1111, the ring assembly 112, and the substrate to a target temperature. The temperature adjusting module may include a heater, a heat transfer medium, a flow path 1110a, or a combination thereof. A heat transfer fluid such as brine and gas flows through the flow path 1110a. In one embodiment, the flow path 1110a is formed in the base 1110, and one or more heaters are disposed in the ceramic member 1111a of the electrostatic chuck 1111. Furthermore, the substrate support unit 11 may include a heat transfer gas supply unit configured to supply heat transfer gas into a gap between the rear surface of the substrate W and the center region 111a. When the heat transfer gas is supplied to the gap between the rear surface of the substrate W and the center region 111a, a gas flow path for the heat transfer gas is provided in the substrate support unit 11. Still furthermore, the substrate support unit 11 is provided with a through hole, which is not illustrated, for accommodating a lifter pin that moves up and down when the substrate W is received or delivered. In the embodiment, the substrate support unit 11 or the main body part 111 corresponds to a substrate support pedestal in the present disclosure. Moreover, in the embodiment, the center region 111a corresponds to a placing surface in the present disclosure.

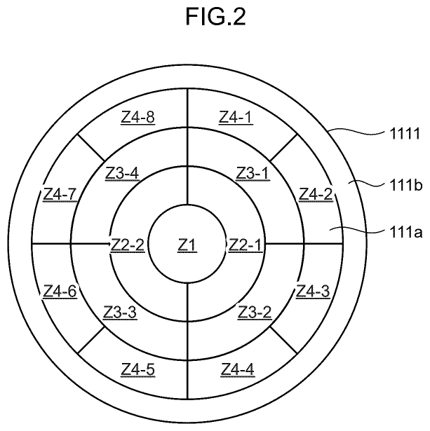

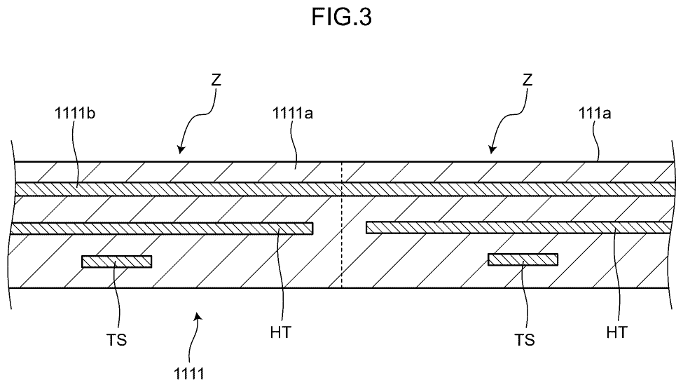

The configuration of the electrostatic chuck 1111 in the substrate support unit 11 will now be described. FIG. 2 is a plan view illustrating an example of the configuration of the electrostatic chuck 1111 according to one embodiment. FIG. 3 is a sectional view illustrating an example of the configuration of the electrostatic chuck 1111 according to one embodiment.

FIG. 2 illustrates a plan view of the upper surface of the electrostatic chuck 1111. The upper surface of the electrostatic chuck 1111 is divided into the center region 111a and the annular region 111b. The center region 111a is a substantially circular region in a plan view. The substrate W is placed on the upper surface of the center region 111a. The diameter of the center region 111a is substantially the same as that of the substrate W, or is slightly smaller than the diameter of the substrate W. The annular region 111b is a region surrounding the center region 111a, and extends in a substantially annular shape. In one embodiment, the upper surface of the annular region 111b is located lower than the upper surface of the center region 111a.

The center region 111a is divided into a plurality of zones Z1, Z2-1, Z2-2, Z3-1 to Z3-4, and Z4-1 to Z4-8. In the following, the zones Z1, Z2-1, Z2-2, Z3-1 to Z3-4, and Z4-1 to Z4-8 may be collectively referred to as a zone Z. Each zone Z is a divided region formed by dividing the center region 111a, and forms a part of the center region 111a. For example, as illustrated in FIG. 2, the center region 111a is divided into a zone Z1 with a circular center. Moreover, the center region 111a is divided into a plurality of concentric annular regions from the circular zone Z1, and each of the annular regions is divided in the peripheral direction into a plurality of arc-shaped Z2-1, Z2-2, Z3-1 to Z3-4, and Z4-1 to Z4-8. The arc-shaped zones Z2-1, Z2-2, Z3-1 to Z3-4, and Z4-1 to Z4-8 are divided into segments whose angular width decreases toward the outer periphery. The method of dividing the zone Z illustrated in FIG. 2 is merely an example, and is not limited thereto. For example, the center region 111a may also be divided into segments such that the radial width of the arc-shaped zone Z narrows toward the outer periphery. Moreover, the center region 111a may also be divided into the zones Z such that the concentric regions from the center each have a fixed angle. Furthermore, the center region 111a may also be divided into the zones Z in a lattice shape. Still furthermore, to finely control the temperature distribution in the center region 111a, the center region 111a may be divided into more zones Z. For example, the center region 111a may be divided into 100 or more zones Z. Still furthermore, in the method of dividing the zone Z illustrated in FIG. 2, the annular region 111b is not divided. However, it is not limited thereto. The annular region 111b may also be divided into a plurality of zones Z. For example, the annular region 111b may be divided into a plurality of arc-shaped zones Z in the peripheral direction.

In the electrostatic chuck 1111, a heater HT is provided in each zone Z. FIG. 3 schematically illustrates a partial section of the two zones Z in the electrostatic chuck 1111. The electrostatic electrode 1111b is disposed in the ceramic member 1111a. Moreover, the heater HT and a temperature sensor TS are disposed in each zone Z in the ceramic member 1111a. The heater HT generates heat when power is supplied, and heats the zone Z.

Returning to FIG. 1. Each heater HT is connected to a heater power source 60. Each temperature sensor TS is connected to a temperature detection unit 61. In FIG. 1, wiring that connect each heater HT to the heater power source 60, and that connect each temperature sensor TS to the temperature detection unit 61, are partially omitted.

The heater power source 60 supplies power to each heater HT. The heater power source 60 can regulate the power supplied to each heater HT. For example, the heater power source 60 performs pulse width modulation (PWM) control on the power supplied to each heater HT. In the PWM control, the output power is controlled by periodically switching on and off in one cycle. By changing the proportion (duty ratio) of the ON period in one cycle, the heater power source 60 controls the power supplied to each heater HT. The heater power source 60 regulates the power supplied to each heater HT, on the basis of control signals received from the controller 2. Each heater HT generates heat by power supplied from the heater power source 60, and heats the zone Z.

The temperature detection unit 61 measures the resistance value of each temperature sensor TS, and on the basis of the measured resistance value, detects the temperature of each zone Z in which each temperature sensor TS is disposed.

The temperature sensor TS may be formed of a material whose resistance value changes according to the temperature. For example, the temperature sensor TS is a thermistor. Moreover, the temperature sensor TS may be a thin film formed of any material made of tungsten, nickel, molybdenum, copper, silver, platinum, and aluminum. The temperature detection unit 61 may detect the temperature of each zone Z, by measuring the current and voltage of the power supplied to each temperature sensor TS, obtaining the resistance value of each temperature sensor TS from the measured current and voltage, and on the basis of the obtained resistance value.

As a result, in the electrostatic chuck 1111, the heat generated by each heater HT is individually controlled, on the basis of the temperature detected by each temperature sensor TS, and the temperature of the zones Z in the center region 111a is individually regulated.

The shower head 13 is configured to introduce at least one processing gas from the gas supply unit 20 into the plasma processing space 10s. The shower head 13 includes at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the gas introduction ports 13c. Moreover, the shower head 13 includes at least one upper electrode. The gas introduction unit may also include one or more side gas injectors (SGIs) attached to one or more opening parts formed on the side wall 10a, in addition to the shower head 13.

The gas supply unit 20 may include at least one gas source 21 and at least one flow controller 22. In one embodiment, the gas supply unit 20 is configured to supply at least one processing gas to the shower head 13 from the gas source 21 corresponding to each processing gas via the flow controller 22 corresponding to each gas source 21. For example, each flow controller 22 may include a mass flow controller or a pressure-controlled flow controller. Moreover, the gas supply unit 20 may include one or more flow modulation devices that modulate or pulse the flow of at least one processing gas.

The power source 30 includes an RF power source 31 coupled to the plasma processing chamber 10 via at least one impedance matching circuit. The RF power source 31 is configured to supply at least one RF signal (RF power) to at least one lower electrode and/or at least one upper electrode. As a result, plasma is formed from at least one processing gas supplied to the plasma processing space 10s. Therefore, the RF power source 31 may function as at least a part of a plasma generation unit that is configured to generate plasma from one or more processing gases in the plasma processing chamber 10. Moreover, by supplying the bias RF signal to at least one lower electrode, a bias potential is generated on the substrate W. Hence, ion components in the formed plasma may be drawn to the substrate W.

In one embodiment, the RF power source 31 includes a first RF generation unit 31a and a second RF generation unit 31b. The first RF generation unit 31a is coupled to at least one lower electrode and/or at least one upper electrode via at least one impedance matching circuit, and is configured to generate a source RF signal (source RF power) for plasma generation. In one embodiment, the source RF signal has a frequency in the range of 10 MHz to 150 MHz. In one embodiment, the first RF generation unit 31a may be configured to generate a plurality of the source RF signals with different frequencies. The generated one or more source RF signals are supplied to at least one lower electrode and/or at least one upper electrode.

The second RF generation unit 31b is coupled to at least one lower electrode via at least one impedance matching circuit, and is configured to generate a bias RF signal (bias RF power). The frequency of the bias RF signal may be the same as or different from the frequency of the source RF signal. In one embodiment, the bias RF signal has a frequency lower than that of the source RF signal. In one embodiment, the bias RF signal has a frequency in the range of 100 kHz to 60 MHz. In one embodiment, the second RF generation unit 31b may be configured to generate a plurality of the bias RF signals with different frequencies. The generated one or more bias RF signals are supplied to at least one lower electrode. Moreover, in various embodiments, at least one of the source RF signal and the bias RF signal may be pulsed.

Furthermore, the power source 30 may include a DC power source 32 coupled to the plasma processing chamber 10. The DC power source 32 includes a first DC generation unit 32a and a second DC generation unit 32b. In one embodiment, the first DC generation unit 32a is connected to at least one lower electrode, and is configured to generate a first DC signal. The generated first DC signal is applied to at least one lower electrode. In one embodiment, the second DC generation unit 32b is connected to at least one upper electrode, and is configured to generate a second DC signal. The generated second DC signal is applied to at least one upper electrode.

In various embodiments, at least one of the first and second DC signals may be pulsed. In this case, a sequence of voltage pulses is applied to at least one lower electrode and/or at least one upper electrode. The voltage pulse may have a pulse waveform with a rectangular shape, a trapezoidal shape, a triangular shape, or a combination thereof. In one embodiment, a waveform generation unit for generating a sequence of voltage pulses from a DC signal is connected between the first DC generation unit 32a and at least one lower electrode. Therefore, the first DC generation unit 32a and the waveform generation unit configure a voltage pulse generation unit. When the second DC generation unit 32b and the waveform generation unit configure the voltage pulse generation unit, the voltage pulse generation unit is connected to at least one upper electrode. The voltage pulse may have a positive polarity or a negative polarity. Moreover, the sequence of voltage pulses may include one or more positive voltage pulses and one or more negative voltage pulses in one cycle. Furthermore, the first and second DC generation units 32a and 32b may be provided in addition to the RF power source 31, and the first DC generation unit 32a may be provided in place of the second RF generation unit 31b.

For example, the exhaust system 40 may be connected to a gas discharge port 10e provided at the bottom of the plasma processing chamber 10. The exhaust system 40 may include a pressure regulating valve and a vacuum pump. The pressure in the plasma processing space 10s is regulated by the pressure regulating valve. The vacuum pump may include a turbo-molecular pump, a dry pump, or a combination thereof.

The controller 2 processes computer-executable instructions for causing the plasma processing device 1 to perform various processes described in the present disclosure. The controller 2 may be configured to control each element in the plasma processing device 1 so that the various processes described herein are executed. In one embodiment, all or part of the controller 2 may be included in the plasma processing device 1. The controller 2 may include a processing unit 2a1, a storage 2a2, and a communication interface 2a3. For example, the controller 2 is implemented by a computer 2a. The processing unit 2a1 reads a computer program from the storage 2a2, and may be configured to perform various control operations by executing the read computer program. The computer program may be stored in the storage 2a2 in advance, or may be obtained via a medium when needed. The obtained computer program is stored in the storage 2a2, and is executed when the processing unit 2a1 reads the computer program from the storage 2a2. The medium may be various storage media readable by the computer 2a, or may be a communication line connected to the communication interface 2a3. The processing unit 2a1 may be a circuit such as central processing unit (CPU). The storage 2a2 may include circuits such as a random access memory (RAM), a read only memory (ROM), a hard disk drive (HDD), a solid state drive (SSD), or a combination thereof. The communication interface 2a3 may communicate with the plasma processing device 1 via a communication line such as a local area network (LAN).

Incidentally, due to structural effects and the like, the thermal resistance of the substrate support unit 11 varies from one zone Z to another. For example, due to effects of a gas flow path, a through hole for accommodating a lifter pin, a structure provided inside, and the like, the thermal resistance of the substrate support unit 11 varies from one zone Z to another. Moreover, for example, the temperature of each zone Z in the substrate support unit 11 is controlled by the heat removed by the heat transfer fluid that flows through the flow path 1110a and the heat input from the heater HT. In the substrate support unit 11, depending on the location where the flow path 1110a is disposed, the calorific value removed by the heat transfer fluid varies from one zone Z to another. For this reason, the thermal resistance of the substrate support unit 11 varies from one zone Z to another. As a result, in the substrate support unit 11, even when the heat input from the heater HT in each zone Z is consistent, the temperature resistance is inconsistent. Hence, the temperature becomes inconsistent.

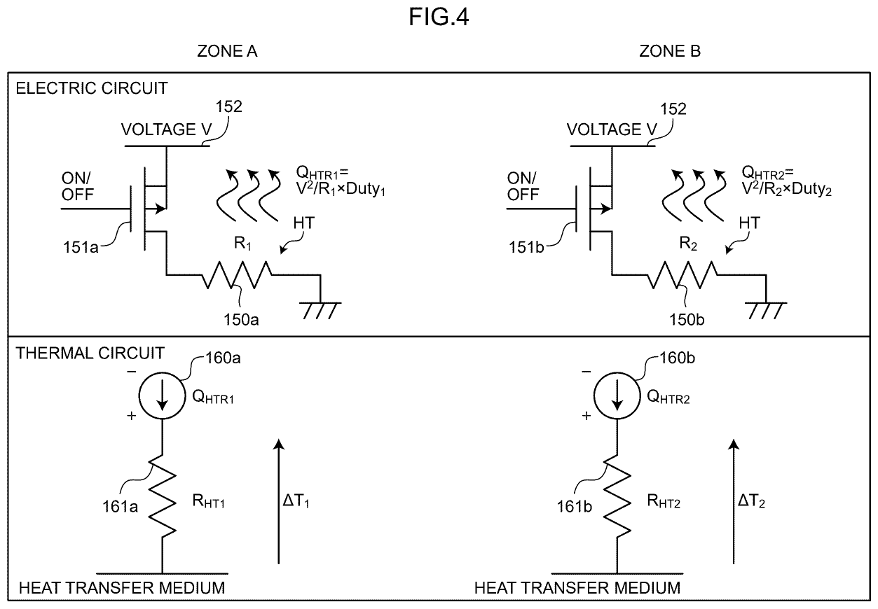

An example of the thermal resistance and calorific value will now be simply described using two zones A and B among the zones Z in the substrate support unit 11 as an example. FIG. 4 is a diagram for explaining the thermal resistance and calorific value of two zones A and B in the substrate support unit 11. The two zones A and B may be the zones Z disposed at the same distance from the center of the electrostatic chuck 1111, or the zones Z disposed at different distances from the center of the electrostatic chuck 1111. Moreover, the two zones A and B may be the zones Z disposed adjacent to each other, or may be the zones Z disposed without being adjacent to each other.

Electric circuits for supplying power to the heater HT in the zones A and B are schematically illustrated on the upper side of FIG. 4. In the zone A, the heater HT is illustrated as a heater resistor 150a with a resistance value of R₁. In the zone B, the heater HT is illustrated as a heater resistor 150b with a resistance value of R₂. The heater resistor 150a is connected to a feeding line 152 via a switch 151a. The heater resistor 150 b is connected to the feeding line 152 via a switch 151 b. A voltage V is applied to the feeding line 152. The switches 151a and 151b are turned on and off by a control signal controlled by PWM. The controller 2 transmits the control signal to the switches 151a and 151b. The controller 2 controls the duty ratio of the control signal supplied to the switches 151a and 151b, according to the set temperature of the zones A and B. When the switches 151a and 151b are turned on, power at voltage V is supplied to the heater resistors 150a and 150b, to generate heat. The calorific value Q_{HTR1} of the heater HT in the zone A can be expressed as the following equation (1-1). The calorific value Q_{HTR2} of the heater HT in the zone B can be expressed as the following equation (1-2).

Q_{HTR1}=V²/R₁×Duty₁ (1-1)

Q_{HTR2}=V²/R₂×Duty₂ (1-2)

In this example,
Duty₁ is the duty ratio when the switch 151a is turned on and off.
Duty₂ is the duty ratio when the switch 151b is turned on and off.

The calorific values Q_{HTR1} and Q_{HTR2} of the heaters HT in the zones A and B increase with an increase in the Duty₁ and Duty₂.

Thermal circuits that illustrate the heat flow in the zones A and B in the substrate support unit 11 are schematically illustrated on the lower side of FIG. 4. The temperature of the zones A and B is controlled by the heat removed by the heat transfer fluid that flows through the flow path 1110a and the heat generated and input by the heater HT. In FIG. 4, the thermal resistance R_{HT1} indicates the difficulty of heat transfer in the zone A, and the thermal resistance R_{HT2} indicates the difficulty of heat transfer in the zone B. The thermal circuit in the zone A can be represented as a circuit in which a resistor 161a with the thermal resistance R_{HT1} is connected in series to a thermal source 160a of the calorific value Q_{HTR1}. The thermal circuit in the zone B can be represented as a circuit in which a resistor 161b with the thermal resistance R_{HT2} is connected in series to a thermal source 160b of the calorific value Q_{HTR2}. The temperature in the zones A and B rises according to the calorific values Q_{HTR1} and Q_{HTR2} of the heaters HT, from the temperature of the heat transfer fluid that flows through the flow path 1110a. The temperature difference ΔT₁ from the heat transfer fluid in the zone A increases with an increase in the calorific value Q_{HTR1}. The temperature difference ΔT₂ from the heat transfer fluid in the zone B increases with an increase in the calorific value Q_{HTR2}.

Due to structural effects and the like in the substrate support unit 11, the thermal resistances R_{HT1} and R_{HT2} vary in the zones A and B. For this reason, even when the heat input from the heater HT is consistent, the thermal resistances R_{HT1} and R_{HT2} vary in the zones A and B. Hence, the temperature becomes inconsistent.

For example, in the substrate support unit 11, the resistance value of the heater HT in each zone Z is made equal. For example, in the zones A and B, the heater resistors 150a and 150b are created so that the resistance value R₁ and the resistance value R₂ become equal.

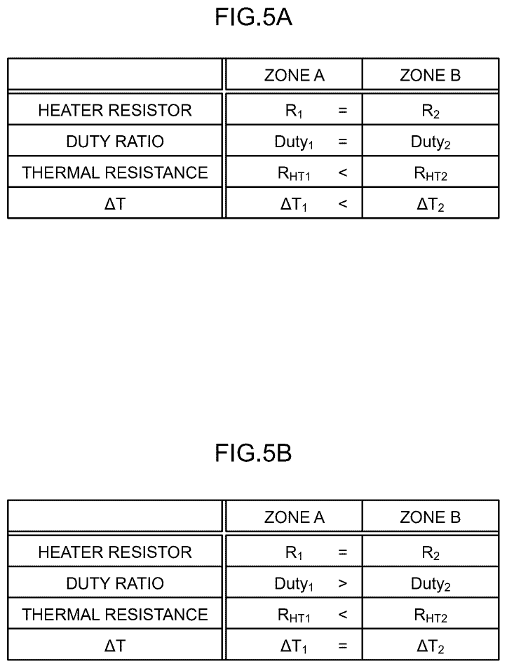

In this example, as a comparative example, an example of temperature control when the resistance value R₁ and the resistance value R₂ are equal will be described. FIG. 5A is a diagram for explaining an example of temperature control in the comparative example. FIG. 5A illustrates a case when the Duty₁ and Duty₂ in the zones A and B are equal. For example, in the substrate support unit 11, the resistance value of the heater HT in each zone Z is made equal. For example, in the zones A and B, the heater resistors 150a and 150b are created so that the resistance value R₁ and the resistance value R₂ become equal. However, due to structural effects and the like, the thermal resistances R_{HT1} and R_{HT2} in the zones A and B are not equal. In FIG. 5A, the thermal resistance R_{HT1} of the zone A is smaller than the thermal resistance R_{HT2} of the zone B (thermal resistance R_{HT1}<thermal resistance R_{HT2}). In this example, when the calorific values Q_{HTR1} and Q_{HTR2} are made equal by supplying power to the heaters HT in the zones A and B at the same duty ratio (Duty₁=Duty₂), the relationship of thermal resistance R_{HT1}<thermal resistance R_{HT2} in the zones A and B is satisfied. Hence, the relationship of temperature difference ΔT₁<temperature difference ΔT₂ is satisfied.

Thus, in the zones A and B, if the calorific values Q_{HTR1} and Q_{HTR2} of the heaters HT are made equal, by making the Duty₁ and Duty₂ equal, the relationship of thermal resistance R_{HT1} <thermal resistance R_{HT2} is satisfied. Hence, the relationship of temperature difference ΔT₁ <temperature difference ΔT₂ is satisfied.

To make the temperature difference ΔT₁ and the temperature difference ΔT₂ equal, the Duty₁ and Duty₂ each need to be changed. FIG. 5B is a diagram for explaining an example of temperature control in the comparative example. FIG. 5B illustrates a case when the Duty₁ and Duty₂ are changed so that the temperature difference ΔT₁ and the temperature difference ΔT₂ become equal. When the temperature difference ΔT₁ and the temperature difference ΔT₂ are made equal, the relationship of thermal resistance R_{HT1} <thermal resistance R_{HT2} is satisfied. Hence, with respect to the duty ratio, the relationship of Duty₁>Duty₂ is satisfied.

Thus, by increasing the duty ratio of the power supplied to the zone B with a high thermal resistance, the zone A with a low thermal resistance can obtain the same temperature difference.

The temperature of the substrate W varies depending on the temperature of each zone Z. For example, to increase the temperature of the substrate W, the duty ratio of the power supplied to the heater HT in each zone Z is increased, to increase the calorific value. Moreover, to lower the temperature of the substrate W, the duty ratio of the power supplied to the heater HT in each zone Z is reduced, to reduce the calorific value.

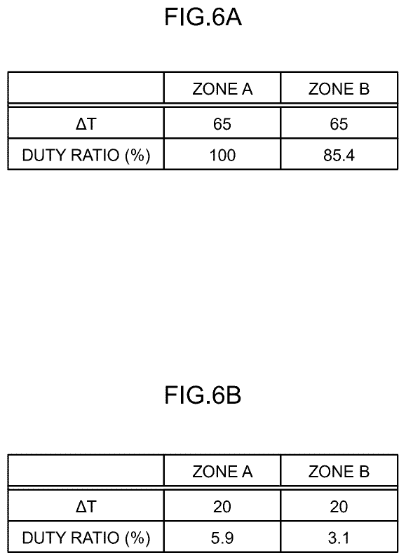

FIG. 6A is a diagram for explaining an example when the temperature of the substrate W is increased by the temperature control in the comparative example. FIG. 6A illustrates an example of the duty ratio (Duty₁ and Duty₂) when the temperature differences ΔT₁ and ΔT₂ in the zones A and B are set to 65° C. The duty ratio is 100% in the zone A, and 85.4% in the zone B. FIG. 6B is a diagram for explaining an example when the temperature of the substrate W is lowered by the temperature control in the comparative example. FIG. 6B illustrates an example of the duty ratio (Duty₁ and Duty₂) when the temperature differences ΔT₁ and ΔT₂ in the zones A and B are set to 20° C. The duty ratio is 5.9% in the zone A, and 3.1% in the zone B.

The duty ratio is the proportion of the ON period in one cycle, and there are upper limit and lower limit to the settable range. For example, once the duty ratio reaches 100%, the duty ratio cannot be increased any further. For this reason, when the duty ratio of the power supplied to the heater HT in any zone Z reaches the upper limit, the temperature of the substrate W cannot be raised any further, even if the duty ratio of the other zones Z has not yet reached the upper limit. For example, in the example of FIG. 6A, the duty ratio of the zone A is 100%. Hence, the temperature of the substrate W cannot be raised any further. Moreover, if the duty ratio of the power supplied to the heater HT in any zone Z reaches the lower limit, the temperature of the substrate W cannot be lowered any further, even if the duty ratio of the other zones Z has not yet reached the lower limit.

Thus, if the thermal resistance of each zone Z varies, the controllable temperature range may be narrowed in controlling the temperature of each zone Z to the same temperature.

Therefore, in the plasma processing device 1 according to the present embodiment, the substrate support unit 11 may be configured such that the resistance value of the heater HT in the zone Z with a small thermal resistance is reduced, and the resistance value of the heater HT in the zone Z with a high thermal resistance is increased. For example, to manufacture the substrate support unit 11, for the zone Z with a low thermal resistance, the heater resistor that functions as the heater HT is configured so that the resistance value becomes small. Moreover, for the zone Z with a high thermal resistance, the heater resistor that functions as the heater HT is configured so that the resistance value becomes large. For example, the substrate support unit 11 is configured such that the thermal resistance ratio of each zone Z in the electrostatic chuck 1111 matches the resistance value ratio of the heater HT provided in each zone Z.

An example of the thermal resistance and calorific value will now be described using the two zones A and B described above among the zones Z as an example.

In the plasma processing device 1 according to the present embodiment, if the thermal resistance R_{HT1} of the zone A is greater than the thermal resistance R_{HT2} of the zone B, the substrate support unit 11 is configured such that the resistance value R₁ of the heater HT in the zone A becomes greater than the resistance value R₂ of the heater HT in the zone B. Moreover, in the plasma processing device 1 according to the present embodiment, if the thermal resistance R_{HT1} of the zone A is smaller than the thermal resistance R_{HT2} of the zone B, the substrate support unit 11 is configured such that the resistance value R₁ of the heater HT in the zone A becomes smaller than the resistance value R₂ of the heater HT in the zone B. For example, the substrate support unit 11 is configured such that the thermal resistance R_{HT1} of the zone A, the thermal resistance R_{HT2} of the zone B, the resistance value R₁ of the heater HT in the zone A, and the resistance value R₂ of the heater HT in the zone B satisfy the following equation (2).

R₂/R₁=R_{HT2}/R_{HT1} (2)

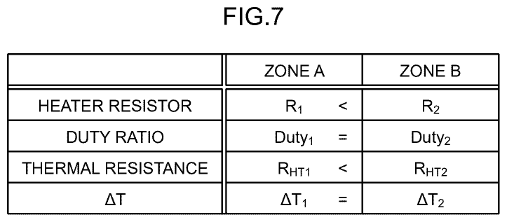

An example of temperature control in the present embodiment will be described using the zones A and B. FIG. 7 is a diagram for explaining an example of temperature control in the present embodiment. The zones A and B satisfy the equation (2) described above. In this case, if power is supplied to the heaters HT in the zones A and B at the same duty ratio (Duty₁=Duty₂), the temperature difference ΔT₁ and the temperature difference ΔT₂ become equal. As a result, by controlling the Duty₁ and Duty₂ in the zones A and B in the same manner, the controller 2 can control the temperature in the zones A and B to the same temperature. The controller 2 controls the duty ratio of the pulse power applied to the heater HT in the zones A and B, according to the resistance value ratio of the resistance value of the heater HT in the zone B with respect to the resistance value of the heater HT in the zone A, and the thermal resistance ratio of the thermal resistance of the zone B with respect to the thermal resistance of the zone A. The controller 2 controls the duty ratio, when the duty ratios of the zone A and the zone B are set to different values, or when the duty ratios are set to the same value. As a result, the plasma processing device 1 according to the embodiment can change the duty ratio (Duty₁ and Duty₂) to the upper limit and lower limit of the settable range. As a result, the plasma processing device 1 according to the embodiment can expand the controllable temperature range in controlling the temperature of each zone Z to the same temperature.

In the embodiment described above, the temperature of each zone Z is controlled to the same temperature, when heat is not input to the substrate support unit 11 from the plasma. Even when heat is input to the substrate support unit 11 from the plasma, by configuring the substrate support unit 11 as in the present embodiment, it is possible to reduce the difference between the duty ratios of the zones Z in controlling the temperature of each zone Z to the same temperature. As a result, even when heat is input to the substrate support unit 11 from the plasma, the plasma processing device 1 can expand the controllable temperature range in controlling the temperature of each zone Z to the same temperature.

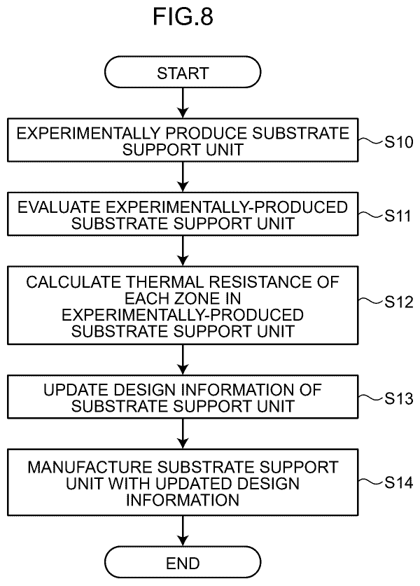

Next, an example of a manufacturing flow of the substrate support unit 11 according to the embodiment will be described. FIG. 8 is a diagram for explaining an example of a manufacturing flow of the substrate support unit 11 according to the embodiment.

At step S10, the substrate support unit 11 is produced experimentally without regulating the resistance value of the heater HT in each zone Z, on the basis of the design information of the substrate support unit 11. For example, the substrate support unit 11 is produced experimentally by setting the resistance values of the heaters HT in the zones Z to the same predetermined value.

At step S11, the substrate support unit 11 produced experimentally at step S10 is evaluated. For example, the temperature of each zone Z is measured, by supplying the same power to the heater HT in each zone Z. For example, similar to when being assembled to the plasma processing device 1, the temperature of each zone Z is measured, by making the heat transfer fluid flow in the flow path 1110a of the substrate support unit 11, and by supplying the same power to the heater HT in each zone Z. Moreover, the duty ratio when the power is supplied to the heater HT in each zone Z is recorded. Due to structural effects and the like, the thermal resistance of the substrate support unit 11 varies from one zone Z to another. For this reason, the temperature of each zone Z varies corresponding to the thermal resistance of each zone Z.

At step S12, the thermal resistance of each zone Z in the experimentally produced substrate support unit 11 is calculated. For example, the temperature difference ΔT from the heat transfer fluid in each zone Z is calculated from the temperature of each zone Z. Moreover, from the duty ratio when power is supplied to the heater HT in each zone Z, the calorific value Q_{HTR} of the heater HT in each zone Z is calculated, using the equations (1-1), (1-2), and the like. Then, from the temperature difference ΔT and the calorific value Q_{HTR} of each zone Z, the thermal resistance R_{HT} of each zone Z is calculated, using the following equation (3).

R_{HT}=ΔT/Q_{HTR} (3)

At step S13, the design information of the substrate support unit 11 is updated such that the resistance value of the heater HT in the zone Z with a small thermal resistance is reduced, and the resistance value of the heater HT in the zone Z with a large thermal resistance is increased, according to the thermal resistance of each zone Z. For example, the resistance value of the heater HT in each zone Z is calculated such that the thermal resistance ratio of each zone Z in the electrostatic chuck 1111 matches the resistance value ratio of the heater HT in each zone Z. Then, the resistance value of the heater HT in each zone Z in the design information of the substrate support unit 11 is updated to the calculated resistance value.

At step S14, the substrate support unit 11 is manufactured, on the basis of the updated design information of the substrate support unit 11. The manufactured substrate support unit 11 is configured such that the resistance value of the heater HT in the zone Z with a small thermal resistance is reduced, and the resistance value of the heater HT in the zone Z with a large thermal resistance is increased.

In FIG. 8, the thermal resistance of each zone Z in the substrate support unit 11 is calculated by experimentally producing the substrate support unit 11. However, the manufacturing flow of the substrate support unit 11 is not limited thereto. For example, the thermal resistance of each zone Z in the substrate support unit 11 may also be theoretically calculated from the design information of the substrate support unit 11.

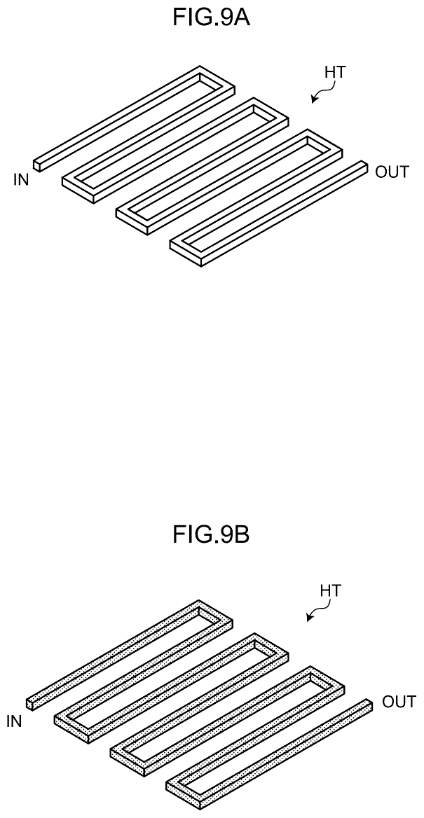

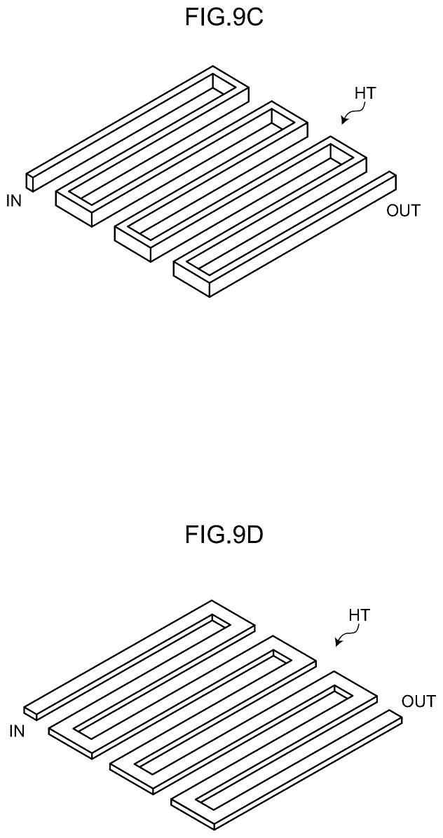

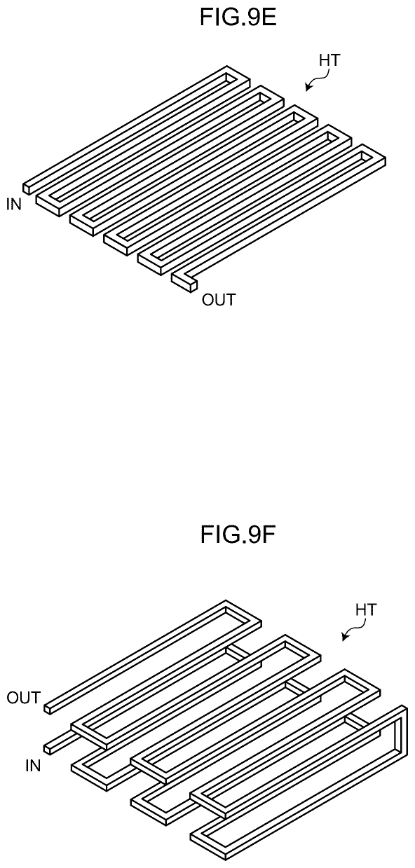

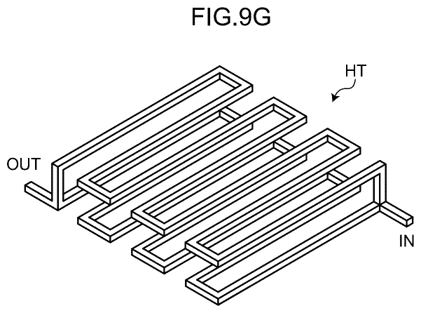

Next, an example of changing the resistance value of the heater HT will be described. The heater HT in each zone Z is formed in a film shape or in a wiring pattern. For example, the heater HT in each zone Z is formed by meander wiring or multilayer wiring. The heaters HT in the zones Z may all have the same configuration, or part thereof may have a different configuration. For example, the heater HT in each zone Z may have a different configuration according to the position of the zone Z. FIG. 9A to FIG. 9G are diagrams each illustrating an example of the configuration of the heater HT according to the embodiment. FIG. 9A illustrates a case when the heater HT is formed by meander wiring. FIG. 9B illustrates a case when the conductive material used for the meander wiring is changed. In the heater HT, the resistance value is increased, by changing the wiring material to a material with low conductivity, and the resistance value is reduced, by changing the wiring material to a material with high conductivity. FIG. 9C illustrates a case when the thickness of the meander wiring is increased. FIG. 9D illustrates a case when the width of the meander wiring is increased. The resistance value of the heater HT is reduced, when the cross section of the wiring is increased, by increasing the thickness of the wiring or increasing the width of the wiring. FIG. 9E illustrates a case when the length of the meander wiring is increased. FIG. 9F illustrates a case when two layers of the meander wiring are connected in series to increase the length. The resistance value of the heater HT is increased, when the length of the wiring is increased, and the resistance value is reduced, when the length of the wiring is reduced. FIG. 9G illustrates a case when the two layers of the meander wiring are connected in parallel. The resistance value of the heater HT is reduced, when the two layers of the meander wiring are connected in parallel.

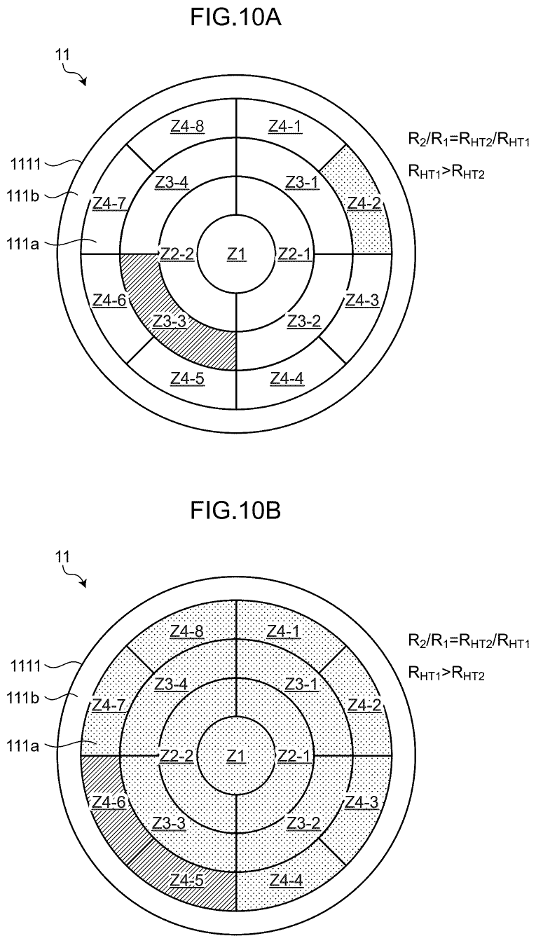

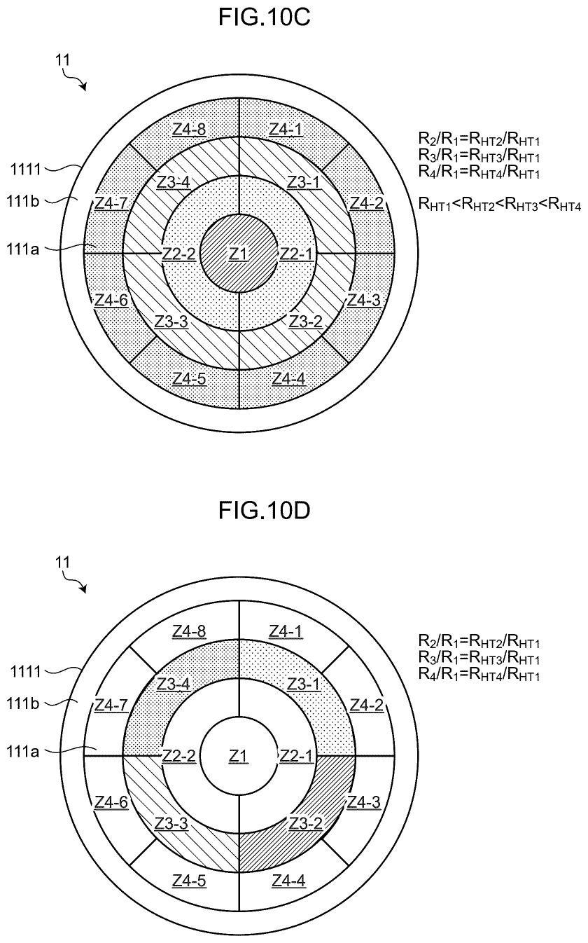

Next, an example of the substrate support unit 11 according to the embodiment will be described. FIG. 10A to FIG. 10D are diagrams each illustrating an example of the substrate support unit 11 according to the embodiment. In FIG. 10A to FIG. 10D, the center region 111a is divided into the zones Z1, Z2-1, Z2-2, Z3-1 to Z3-4, and Z4-1 to Z4-8.

FIG. 10A illustrates a case when the thermal resistances of the zone Z3-3 and the zone Z4-2 that are disposed without being adjacent to each other differ. The zone Z3-3 and the zone Z4-2 are disposed at different distances from the center of the electrostatic chuck 1111. In FIG. 10A, for the zone Z3-3, the thermal resistance is R_{HT1}, and the resistance value of the heater HT is R₁. Moreover, for the zone Z4-2, the thermal resistance is R_{HT2}, and the resistance value of the heater HT is R₂. In FIG. 10A, the thermal resistance is R_{HT1}>R_{HT2}. The thermal resistance R_{HT1} of the zone Z3-3 and the resistance value R₁ of the heater HT, and the thermal resistance R_{HT2} of the zone Z4-2 and the resistance value R₂ of the heater HT satisfy the equation (2) described above. Therefore, in FIG. 10A, it is possible to expand the controllable temperature range in controlling the temperature of the zone Z3-3 and the zone Z4-2 to the same temperature.

FIG. 10B illustrates a case when the thermal resistances of some zones Z differ. For example, in the substrate support unit 11 illustrated in FIG. 10B, there are many terminals and through holes in the zones Z4-5 and Z4-6 at the outer peripheral side. Hence, the thermal resistance may be greater than that in the other zones Z. In FIG. 10B, for the zones Z4-5 and Z4-6, the thermal resistance is R_{HT1}, and the resistance value of the heater HT is R₁. Moreover, for the remaining zones Z, the thermal resistance is R_{HT2}, and the resistance value of the heater HT is R₂. The thermal resistance R_{HT1} and the resistance value R₁ of the heater HT in the zones Z4-5 and Z4-6, and the thermal resistance R_{HT2} and the resistance value R₂ of the heater HT in the other zones Z satisfy the equation (2) described above. Therefore, in FIG. 10B, it is possible to expand the controllable temperature range in controlling the temperature of each zone Z to the same temperature.

FIG. 10C illustrates a case when the thermal resistance of each zone Z from the center differs. In FIG. 10C, for the zone Z1, the thermal resistance is R_{HT1} and the resistance value of the heater HT is R₁. Moreover, for the concentric zones Z2-1 and Z2-2, the thermal resistance is R_{HT2}, and the resistance value of the heater HT is R₂. Furthermore, for the concentric zones Z3-1 to Z3-4, the thermal resistance is R_{HT3}, and the resistance value of the heater HT is R₃. Still furthermore, for the concentric zones Z4-1 to Z4-8, the thermal resistance is R_{HT4}, and the resistance value of the heater HT is R₄. In FIG. 10C, with respect to the thermal resistance, the relationship of R_{HT1} <R_{HT2}<R_{HT3}<R_{HT4} is satisfied. When the thermal resistance R_{HT1} and the resistance value R₁ of the heater HT in the zone Z1 are used as references, the thermal resistances R_{HT2}, R_{HT3}, and R_{HT4}, and the resistance values R₂, R₃, and R₄ of the heater HT satisfy the equation (2) described above. Therefore, in FIG. 10C, it is possible to expand the controllable temperature range in controlling the temperature of each zone Z to the same temperature.

FIG. 10D illustrates a case when the thermal resistance of the zones Z3-1 to Z3-4 disposed at the same distance from the center differs. In FIG. 10D, for the zone Z3-1, the thermal resistance is R_{HT1} and the resistance value of the heater HT is R₁. Moreover, for the zone Z3-2, the thermal resistance is R_{HT2}, and the resistance value of the heater HT is R₂. Furthermore, for the zone Z3-3, the thermal resistance is R_{HT3}, and the resistance value of the heater HT is R₃. Still furthermore, for the zone Z3-4, the thermal resistance is R_{HT4}, and the resistance value of the heater HT is R₄. When the thermal resistance R_{HT1} and the resistance value R₁ of the heater HT in the zone Z3-1 are used as references, the thermal resistances R_{HT2}, R_{HT3}, and R_{HT4}, and the resistance values R₂, R₃, and R₄ of the heater HT satisfy the equation (2) described above. Therefore, in FIG. 10D, it is possible to expand the controllable temperature range in controlling the temperature of the zones Z3-1 to Z3-4 to the same temperature.

As described above, the plasma processing device 1 according to the embodiment includes the plasma processing chamber 10, the substrate support unit 11, and the controller 2. The substrate support unit 11 is disposed in the plasma processing chamber 10, and includes the base 1110 and the electrostatic chuck 1111 disposed on the base 1110. The electrostatic chuck 1111 includes the zone A and the zone B that is different from the zone A, and the heater HT is disposed in the zone A and the heater HT is disposed in the zone B. The controller 2 is configured to control the duty ratio of the pulse power applied to the heater HT in the zone A and the pulse power applied to the heater HT in the zone B, according to the resistance value ratio of the resistance value of the heater HT in the zone B with respect to the resistance value of the heater HT in the zone A, and the thermal resistance ratio of the thermal resistance of the substrate support unit 11 corresponding to the zone B with respect to the thermal resistance of the substrate support unit 11 corresponding to the zone A. As a result, the plasma processing device 1 can expand the controllable temperature range in controlling the temperature of the zones A and B to the same temperature.

Moreover, in the electrostatic chuck 1111, the center region 111a on which the substrate W is placed is divided into the zones Z including the zone A and the zone B. The substrate support unit 11 is configured such that a plurality of the heaters HT including the heater HT in the zone A and the heater HT in the zone B are individually provided in each zone Z, and the resistance value of the heater HT increases with an increase in the thermal resistance of the zone Z. As a result, the plasma processing device 1 can expand the controllable temperature range in controlling the temperature of each zone Z to the same temperature.

Moreover, the substrate support unit 11 is configured such that the thermal resistance ratio of each zone Z matches the resistance value ratio of the heater HT provided in each zone Z. As a result, the plasma processing device 1 can expand the controllable temperature range in controlling the temperature of each zone Z to the same temperature.

Furthermore, in the substrate support unit 11, when the thermal resistance of the zone A is greater than the thermal resistance of the zone B, the resistance value of the heater HT in the zone A is configured greater than the resistance value of the heater HT in the zone B, and when the thermal resistance of the zone A is smaller than the thermal resistance of the zone B, the resistance value of the heater HT in the zone A is configured smaller than the resistance value of the heater HT in the zone B. As a result, the plasma processing device 1 can expand the controllable temperature range in controlling the temperature of the zones A and B to the same temperature.

Still furthermore, the substrate support unit 11 is configured such that the equation (2) described above is satisfied, where the thermal resistance of the zone A is R_{HT1}, the thermal resistance of the zone B is R_{HT2}, the resistance value of the heater HT in the zone A is R₁, and the resistance value of the heater HT in the zone B is R₂. As a result, the plasma processing device 1 can expand the controllable temperature range in controlling the temperature of the zones A and B to the same temperature.

Still furthermore, the zone A (for example, the zone Z3-3 in FIG. 10A) and the zone B (for example, the zone Z4-2 in FIG. 10A) are disposed at different distances from the center of the electrostatic chuck 1111. As a result, the plasma processing device 1 can expand the controllable temperature range in controlling the temperature of the zones A and B disposed at different distances from the center of the electrostatic chuck 1111 to the same temperature.

Still furthermore, the zone A (for example, the zone Z3-1 in FIG. 10D) and the zone B (for example, the zone Z3-3 in FIG. 10D) are disposed at the same distance from the center of the electrostatic chuck 1111. As a result, the plasma processing device 1 can expand the controllable temperature range in controlling the temperature of the zones A and B disposed at the same distance from the center of the electrostatic chuck 1111 to the same temperature.

Still furthermore, the zone A (for example, the zone Z3-1 in FIG. 10D) and the zone B (for example, the zone Z3-2 in FIG. 10D) are disposed adjacent to each other. As a result, the plasma processing device 1 can expand the controllable temperature range in controlling the temperature of the zones A and B disposed adjacent to each other to the same temperature.

Still furthermore, the zone A (for example, the zone Z3-3 in FIG. 10A) and the zone B (for example, the zone Z4-2 in FIG. 10A) are disposed without being adjacent to each other. As a result, the plasma processing device 1 can expand the controllable temperature range in controlling the temperature of the zones A and B that are disposed without being adjacent to each other to the same temperature.

Still furthermore, the electrostatic chuck 1111 includes a third zone (for example, the zone Z3-3 or zone Z3-4 in FIG. 10D) that is different from the zone A (for example, the zone Z3-1 in FIG. 10D) and the zone B (for example, the zone Z3-2 in FIG. 10D). The heater HT is disposed in the zone 3. In the substrate support unit 11, when the thermal resistance of the zone A is greater than the thermal resistance of the third zone, the resistance value of the heater HT in the zone A is configured greater than the resistance value of the heater HT in the third zone, and when the thermal resistance of the zone A is smaller than the thermal resistance of the third zone, the resistance value of the heater HT in the zone A is configured smaller than the resistance value of the heater HT in the third zone. As a result, the plasma processing device 1 can expand the controllable temperature range in controlling the temperature of the zones A and B, and the third zone to the same temperature.

Although the embodiment has been described above, the embodiment disclosed herein should be considered illustrative and not restrictive in all aspects. Indeed, the embodiment described above may be embodied in various forms. Moreover, the embodiment described above may be omitted, substituted, or modified in various ways without departing from the spirit and scope of the claims.

For example, in the above embodiment, a plasma process is performed on the semiconductor wafer serving as the substrate W. However, it is not limited thereto. The substrate W may be in any form.

Furthermore, in the above embodiment, the plasma processing system performs the plasma etching process. However, it is not limited thereto. Any device in which the heater HT is provided in each zone Z obtained by dividing a placing surface 114 of the electrostatic chuck 1111 and that performs a plasma process may be used. For example, the plasma processing device may be a film forming apparatus that generates plasma and forms a film.

The embodiment disclosed herein should be considered illustrative and not restrictive in all aspects. Indeed, the above embodiment may be embodied in various forms. Still furthermore, the above embodiment may be omitted, substituted, or modified in various ways without departing from the spirit and scope of the appended claims.

Regarding the above embodiment, the following additional notes are disclosed.

According to the present disclosure, it is possible to expand the controllable temperature range in controlling the temperature of each zone to the same temperature.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

In connection with the above embodiment, the following notes are further disclosed.

### Note 1

A plasma processing device, comprising:
a plasma processing chamber;
a substrate support pedestal disposed in the plasma processing chamber, and including a base and an electrostatic chuck disposed on the base; and
a controller; wherein
the electrostatic chuck includes a first zone and a second zone that is different from the first zone,
a first heater is disposed in the first zone,
a second heater is disposed in the second zone, and
the controller is configured to control a duty ratio of a pulse power applied to the first heater and a pulse power applied to the second heater, according to a resistance value ratio of a resistance value of the second heater with respect to a resistance value of the first heater, and a thermal resistance ratio of thermal resistance of the substrate support pedestal corresponding to the second zone with respect to thermal resistance of the substrate support pedestal corresponding to the first zone.

### Note 2

The plasma processing device according to note 1, wherein
in the electrostatic chuck, a placing surface on which a substrate is placed is divided into a plurality of zones including the first zone and the second zone, and
the substrate support pedestal is configured such that a plurality of heaters including the first heater and the second heater are individually provided in each of the zones, and the resistance value of the heater increases with an increase in the thermal resistance of the zone.

### Note 3

The plasma processing device according to note 2, wherein the substrate support pedestal is configured such that the thermal resistance ratio of each zone matches the resistance value ratio of the heater provided in each zone.

### Note 4

The plasma processing device according to note 1, wherein in the substrate support pedestal, when the thermal resistance of the first zone is greater than the thermal resistance of the second zone, the resistance value of the first heater is configured greater than the resistance value of the second heater, and when the thermal resistance of the first zone is smaller than the thermal resistance of the second zone, the resistance value of the first heater is configured smaller than the resistance value of the second heater.

### Note 5

The plasma processing device according to note 4, wherein the substrate support pedestal is configured to satisfy the equation (2) described above, where the thermal resistance of the first zone is R_{HT1}, the thermal resistance of the second zone is R_{HT2}, the resistance value of the first heater is R₁, and the resistance value of the second heater is R₂:

### Note 6

The plasma processing device according to any one of notes 1 to 5, wherein the first zone and the second zone are disposed at different distances from a center of the electrostatic chuck.

### Note 7

The plasma processing device according to any one of notes 1 to 5, wherein the first zone and the second zone are disposed at a same distance from a center of the electrostatic chuck.

### Note 8

The plasma processing device according to any one of notes 1 to 7, wherein the first zone and the second zone are disposed adjacent to each other.

### Note 9

The plasma processing device according to any one of notes 1 to 7, wherein the first zone and the second zone are disposed without being adjacent to each other.

### Note 10

The plasma processing device according to note 4 or 5, wherein
the electrostatic chuck includes a third zone different from the first zone and the second zone,
a third heater is disposed in the third zone, and
in the substrate support pedestal, when the thermal resistance of the first zone is greater than the thermal resistance of the third zone, the resistance value of the first heater is configured greater than the resistance value of the third heater, and when the thermal resistance of the first zone is smaller than the thermal resistance of the third zone, the resistance value of the first heater is configured smaller than the resistance value of the third heater.

### Note 11

The plasma processing device according to any one of notes 1 to 10, wherein at least one of the first heater and the second heater is formed in a film shape or in a wiring pattern.

### Note 12

The plasma processing device according to note 11, wherein at least one of the first heater and the second heater is formed by meander wiring or multilayer wiring.

What is claimed is:

1. A plasma processing device, comprising:
a plasma processing chamber;
a substrate support pedestal disposed in the plasma processing chamber, and including a base and an electrostatic chuck disposed on the base; and
a controller circuit; wherein
the electrostatic chuck includes a first zone and a second zone that is different from the first zone,
a first heater is disposed in the first zone,
a second heater is disposed in the second zone, and
the controller circuit is configured to control a duty ratio of a pulse power applied to the first heater and a pulse power applied to the second heater, according to a resistance value ratio of a resistance value of the second heater with respect to a resistance value of the first heater, and a thermal resistance ratio of thermal resistance of the substrate support pedestal corresponding to the second zone with respect to thermal resistance of the substrate support pedestal corresponding to the first zone.

2. The plasma processing device according to claim 1, wherein
in the electrostatic chuck, a placing surface on which a substrate is placed is divided into a plurality of zones including the first zone and the second zone, and
the substrate support pedestal is configured such that a plurality of heaters including the first heater and the second heater are individually provided in each of the zones, and the resistance value of the heater increases with an increase in the thermal resistance of the zone.

3. The plasma processing device according to claim 2, wherein the substrate support pedestal is configured such that the thermal resistance ratio of each zone matches the resistance value ratio of the heater provided in each zone.

4. The plasma processing device according to claim 1, wherein in the substrate support pedestal, when the thermal resistance of the first zone is greater than the thermal resistance of the second zone, the resistance value of the first heater is configured greater than the resistance value of the second heater, and when the thermal resistance of the first zone is smaller than the thermal resistance of the second zone, the resistance value of the first heater is configured smaller than the resistance value of the second heater.

5. The plasma processing device according to claim 4, wherein the substrate support pedestal is configured to satisfy a following equation (1), where the thermal resistance of the first zone is R_{HT1}, the thermal resistance of the second zone is R_{HT2}, the resistance value of the first heater is R₁, and the resistance value of the second heater is R₂:
R₂/R₁=R_{HT2}/R_{HT1} (1).

6. The plasma processing device according to claim 1, wherein the first zone and the second zone are disposed at different distances from a center of the electrostatic chuck.

7. The plasma processing device according to claim 1, wherein the first zone and the second zone are disposed at a same distance from a center of the electrostatic chuck.

8. The plasma processing device according to claim 1, wherein the first zone and the second zone are disposed adjacent to each other.

9. The plasma processing device according to claim 1, wherein the first zone and the second zone are separate from each other.

10. The plasma processing device according to claim 4, wherein
the electrostatic chuck includes a third zone different from the first zone and the second zone,
a third heater is disposed in the third zone, and
in the substrate support pedestal, when the thermal resistance of the first zone is greater than the thermal resistance of the third zone, the resistance value of the first heater is configured greater than the resistance value of the third heater, and when the thermal resistance of the first zone is smaller than the thermal resistance of the third zone, the resistance value of the first heater is configured smaller than the resistance value of the third heater.

11. The plasma processing device according to claim 1, wherein at least one of the first heater and the second heater is formed in a film shape.

12. The plasma processing device according to claim 1, wherein at least one of the first heater and the second heater is formed in a wiring pattern.

13. The plasma processing device according to claim 12, wherein at least one of the first heater and the second heater is formed by meander wiring.

14. The plasma processing device according to claim 12, wherein at least one of the first heater and the second heater is formed by multilayer wiring.

15. The plasma processing device according to claim 1, further comprising temperature sensors disposed in the first zone and the second zone, respectively.

16. The plasma processing device according to claim 15, wherein at least one of the temperature sensors is a thermistor.

17. The plasma processing device according to claim 15, wherein at least one of the temperature sensors is formed of a thin film including one of tungsten, nickel, molybdenum, copper, silver, platinum, and aluminum.

18. The plasma processing device according to claim 1, wherein the base includes a conductive member, and the conductive member is as a lower electrode.

19. The plasma processing device according to claim 18, further comprising a radio frequency (RF) power source coupled to the lower electrode, wherein the RF power source is configured to supply an RF signal to the lower electrode to generate plasma.

20. The plasma processing device according to claim 1, wherein the electrostatic chuck comprises a center region for supporting a substrate, and the center region is divided into a plurality of concentric annular regions.
